(19) United States
(12) Patent Application Publication
(10) Pub. No.: US 2015/0028482 A1
(43) Pub. Date: Jan. 29, 2015

(54) DEVICE LAYOUT FOR REDUCING THROUGH-SILICON-VIA STRESS

(71) Applicant: Globalfoundries Inc., Grand Cayman, KY (US)

(72) Inventors: Guoxiang Ning, Ballston Lake, NY (US); Ming Lei, Ballston Lake, NY (US); Paul Ackmann, Gansevoort, NY (US)

(73) Assignee: GLOBALFOUNDRIES Inc., Grand Cayman, KY (US)

(21) Appl. No.: 13/948,442

(22) Filed: Jul. 23, 2013

(51) Int. Cl. H01L 23/48; H01L 23/00; H01L 21/768

(52) U.S. Cl. CPC H01L 23/481; H01L 21/76877; H01L 23/562
USPC 257/741; 438/667

(57) ABSTRACT

Approaches for reducing through-silicon via (TSV) stress are provided. Specifically, provided is a device comprising a substrate and a TSV formed in the substrate, the TSV having an element patterned therein. The TSV further comprises a set of openings adjacent the element that are subsequently filled with a TSV fill material. The element may be patterned according to any number of shapes (e.g., circle, oval, rectangle, etc.) to optimize the stress distribution for the TSV. The element is patterned and provided within the TSV in order to reduce or compensate for stress forces caused by a change in volume of the conductive fill materials of the openings of the TSV. These approaches apply to both single TSVs and a plurality of TSVs (e.g., arranged as a matrix).

### TECHNICAL FIELD

This invention relates generally to integrated circuit layout optimization and, more particularly, to a device layout for reducing through-silicon-via (TSV) stress.

### RELATED ART

Microelectronic elements generally comprise a thin slab of a semiconductor material, such as silicon or gallium arsenide, commonly called a die or a semiconductor chip. Semiconductor chips are commonly provided as individual, prepackaged units. In some unit designs, the semiconductor chip is mounted to a substrate or chip carrier, which is in turn mounted on a circuit panel, such as a printed circuit board.

The active circuitry is fabricated in a first face of the semiconductor chip (e.g., a front surface). To facilitate electrical connection to the active circuitry, the chip is provided with bond pads on the same face. The bond pads are typically placed in a regular array either around the edges of the die or, for many memory devices, in the die center. The bond pads are generally made of a conductive metal, such as copper, or aluminum, around 0.5 μm thick. The bond pads could include a single layer or multiple layers of metal. The size of the bond pads will vary with the device type but will typically measure tens to hundreds of microns on a side.

Through-silicon vias (TSVs) are used to connect the bond pads with a second face of the semiconductor chip opposite the first face (e.g., a rear surface). A conventional via includes a hole penetrating through the semiconductor chip and a conductive material extending through the hole from the first face to the second face. The bond pads may be electrically connected to vias to allow communication between the bond pads and conductive elements on the second face of the semiconductor chip.

Conventional TSV holes may reduce the portion of the first face that can be used to contain the active circuitry. Such a reduction in the available space on the first face that can be used for active circuitry may increase the amount of silicon required to produce each semiconductor chip, thereby potentially increasing the cost of each chip.

Conventional vias may also have reliability challenges because of non-optimal stress distributions inside the vias, and a mismatch of the coefficient of thermal expansion (CTE) between a semiconductor chip, for example, and the structure to which the chip is bonded. Furthermore, when conductive vias within a semiconductor chip are insulated by a relatively thin and/or stiff dielectric material, significant stresses may be present. In addition, when the semiconductor chip is bonded to conductive elements of a polymeric substrate, the electrical connections between the chip and the higher CTE structure of the substrate will be under stress due to CTE mismatch.

One prior art approach creates a stress buffer to reduce stress on devices and decrease a keep-out-zone (KOZ). The KOZ typically defines a particular area within a die such as an interposer that surrounds a TSV in which active circuit elements are not to be located or implemented in order to avoid stress related performance issues with the active circuit elements. When the number of TSVs increases, however, the many KOZs defined surrounding each TSV can significantly reduce the usable area of a die for implementing active circuit elements. Moreover, the superposition of stress-fields from two or more TSVs can increase the difficulty of eliminating TSV-induced stress completely.

In some cases, the KOZ is defined according to degradation in one or more operating characteristics of an active circuit element such as drive current or the like. In this manner, the KOZ is defined as ending at a perimeter outside of which the selected operating characteristic of the active circuit element implemented at that location is degraded by a predetermined amount or percentage or not at all (as compared to the case in which no TSV is present). However, using measures of degradation in operating characteristics of active circuit elements can still lead to situations in which the TSV-induced stress negatively affects one or more active circuit elements of a circuit block.

### SUMMARY

In general, approaches for reducing through-silicon via (TSV) stress are provided. Specifically, provided is a device comprising a substrate and a TSV formed in the substrate, the TSV having an element patterned therein. The TSV further comprises a set of openings adjacent the element that are subsequently filled with a TSV fill material. The element may be patterned according to any number of layout shapes (e.g., circle, oval, rectangle, etc.) to optimize the stress distribution for the TSV. The element is patterned and provided within the TSV in order to reduce or compensate for stress forces caused by a pronounced change in volume of the conductive fill materials of the openings of the TSV. In this manner, the high risk of creating cracks and delamination events in conventional semiconductor devices may be significantly reduced. These approaches apply to both single TSVs and a plurality of TSVs (e.g., arranged as a matrix).

One aspect of the present invention includes a device comprising a substrate; and a through-silicon-via (TSV) formed in the substrate, the TSV having a substantially vertical element patterned therein.

Another aspect of the present invention includes an integrated circuit (IC) device for reducing through-silicon-via (TSV) stress, the IC device comprising: a substrate; and a TSV formed in the substrate, the TSV having a substantially vertical element patterned therein.

Yet another aspect of the present invention provides a method for reducing through-silicon-via (TSV) stress in an integrated circuit (IC) device, the method comprising: forming a through-silicon-via (TSV) in a substrate of the IC device, the TSV including a substantially vertical element patterned in a central portion therein.

### BRIEF DESCRIPTION OF THE DRAWINGS

These and other features of this invention will be more readily understood from the following detailed description of the various aspects of the invention taken in conjunction with the accompanying drawings in which:

FIGS. 1(a)-1(d) show cross sectional views of the formation of a TSV in an IC device according to illustrative embodiments;

FIG. 2(a) shows a cross-sectional view of the TSV and element formed therein according to illustrative embodiments;

FIG. 2(b) shows a top view of the TSV and element of FIG. 2(a) according to illustrative embodiments;

FIGS. 3(a)-3(e) show top views of various element layouts according to illustrative embodiments;

FIGS. 4(a)-4(d) show top views of various element layouts according to illustrative embodiments;

FIG. 5 shows a top view of a plurality of TSVs according to illustrative embodiments; and

FIGS. 6(a) and 6(b) show top views of a TSV matrix according to illustrative embodiments.

The drawings are not necessarily to scale. The drawings are merely representations, not intended to portray specific parameters of the invention. The drawings are intended to depict only typical embodiments of the invention, and therefore should not be considered as limiting in scope. In the drawings, like numbering represents like elements.

### DETAILED DESCRIPTION

Exemplary embodiments will now be described more fully herein with reference to the accompanying drawings, in which exemplary embodiments are shown. Described are methods and techniques used for reducing through-silicon via (TSV) stress. Specifically, provided is a device comprising a substrate and a TSV formed in the substrate, the TSV having a substantially vertical element patterned therein. The TSV further comprises a set of openings adjacent the element that are subsequently filled with a TSV fill material. The element may be patterned according to any number of shapes (e.g., circle, oval, rectangle, etc.) to optimize the stress distribution for the TSV. The element is patterned and provided within the TSV in order to reduce or compensate for stress forces caused by a pronounced change in volume of the conductive fill materials of the openings of the TSV. In this manner, the high risk of creating cracks and delamination events in conventional semiconductor devices may be significantly reduced. These approaches apply to both single TSVs and a plurality of TSVs (e.g., arranged as a matrix).

It will be appreciated that this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. The terminology used herein is for the purpose of describing particular embodiments only and is not intended to be limiting of this disclosure. For example, as used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Reference throughout this specification to “one embodiment,” “an embodiment,” “embodiments,” “exemplary embodiments,” or similar language means that a particular feature, structure, or characteristic described in connection with the embodiment is included in at least one embodiment of the present invention. Thus, appearances of the phrases “in one embodiment,” “in an embodiment,” “in embodiments” and similar language throughout this specification may, but do not necessarily, all refer to the same embodiment.

The terms “overlying” or “atop”, “positioned on” or “positioned atop”, “underlying”, “beneath” or “below” mean that a first element, such as a first structure, e.g., a first layer, is present on a second element, such as a second structure, e.g. a second layer, wherein intervening elements, such as an interface structure, e.g. interface layer, may be present between the first element and the second element.

As used herein, “depositing” may include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

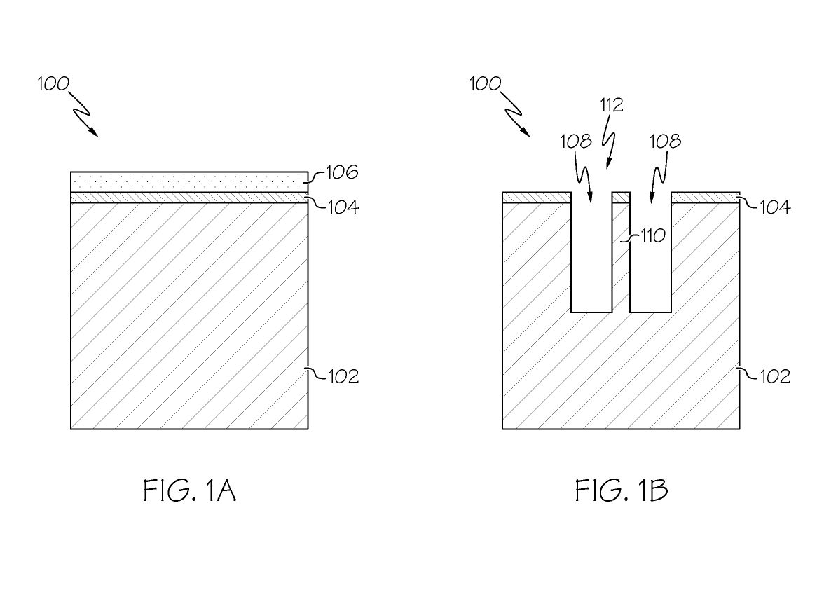

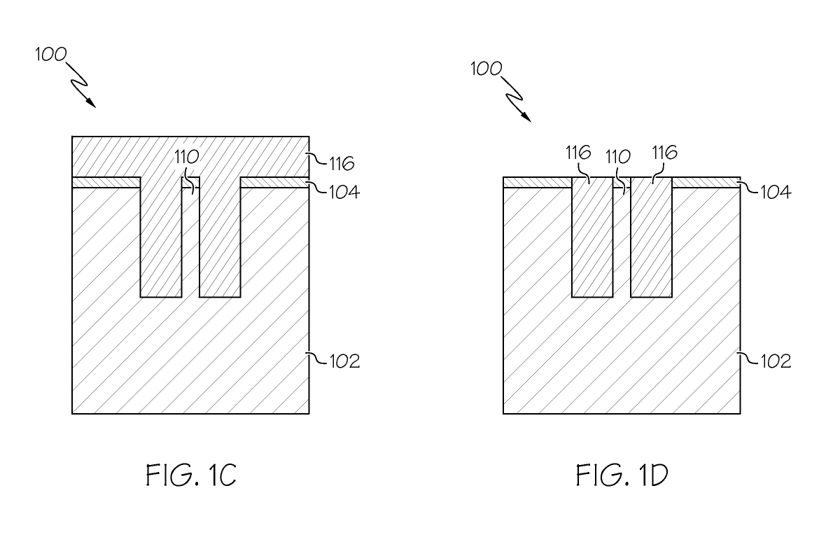

With reference now to the figures, FIGS. 1(a)-1(b) depict an approach for forming a TSV in an IC device according to an illustrative embodiment. As shown in FIG. 1(a), IC device 100 comprises a substrate 102 having a capping layer 104 and a photoresist (PR) 106 formed over top. In one embodiment, substrate 102 includes a silicon substrate (e.g., wafer). The term “substrate” as used herein is intended to include a semiconductor substrate, which may comprise a semiconductor wafer (e.g., silicon, SiGe, or an SOI wafer) or one or more die on a wafer, and any epitaxial layers or other type semiconductor layers formed thereover or associated therewith. A portion or entire semiconductor substrate may be amorphous, polycrystalline, or single-crystalline. In addition to the aforementioned types of semiconductor substrates, the semiconductor substrate employed in the present invention may also comprise a hybrid oriented (HOT) semiconductor substrate in which the HOT substrate has surface regions of different crystallographic orientation. The semiconductor substrate may be doped, undoped or contain doped regions and undoped regions therein. The semiconductor substrate may contain regions with strain and regions without strain therein, or contain regions of tensile strain and compressive strain.

A set of openings 108 is then formed through capping layer 104 and into substrate 102, thus patterning an element 110 into TSV 112, as shown in FIG. 1(b). Sidewall surfaces of each opening 108 may extend in a vertical or substantially vertical direction downwardly from capping layer 104 substantially at right angles. Anisotropic etching processes, laser dicing, laser drilling, mechanical removal processes, e.g., sawing, milling, ultrasonic machining, among others, can be used to form openings 108 having essentially vertical surfaces. It will be appreciated that no additional masks are required, as the patterning shown in this embodiment is achievable with existing manufacturing flows.

Next, a TSV fill material 116 is formed over device 100 including within each opening 108, as shown in FIG. 1(c). In various embodiments, TSV material 116 comprises a conductive fill material, e.g., a core metal such as copper, and at least one barrier layer. TSV fill material 116 is then planarized, e.g., via chemical mechanical planarization (CMP), selective to capping layer 104, as shown in FIG. 1(d).

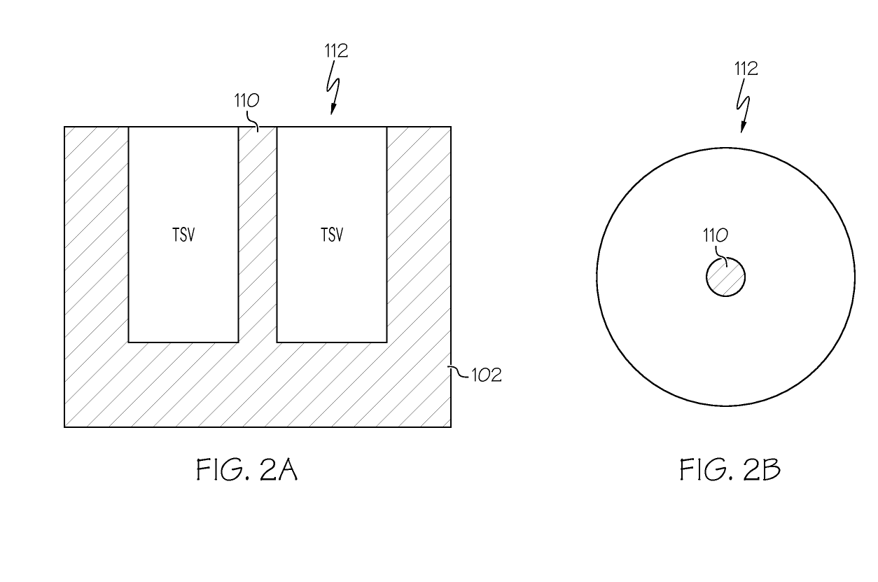

Referring now to FIGS. 2(a) and 2(b), a cross sectional view and top view, respectively, of TSV 112 will be shown and described in greater detail. In this embodiment, TSV 112 comprises element 110, which may be a 3-D column/pillar extending vertically within TSV 112 between substrate 102 and capping layer 104. As shown in FIG. 2(b), element 110 comprises a substantially circular shaped column positioned in a center area of TSV 112. Element 110 may have an appropriate thickness and material composition so as to act as a stress buffer material. That is, element 110 may be in contact with the substrate 102 and also with any materials above TSV 112 so as to reduce the effect of a difference in volume change caused by temperature variations between the material of substrate 102 and any other materials of the levels of IC device 100 and TSV fill material 116. To this end, element 110 may be provided with a thickness of several hundred nanometers to approximately one micrometer or more with an appropriate material composition so as to respond to the difference in volume change without producing undue stress forces in IC device 100 (from 0.1 to 0.5 times of TSV diameter). In one embodiment, element 110 may be comprised of silicon, which may thus respond in a resilient manner to significant volume changes of TSV fill material 116 in openings 108. In other embodiments, element 110 may comprise a very stiff material, such as silicon nitride, in order to efficiently confine a fill metal in combination with an appropriately selected resilient material.

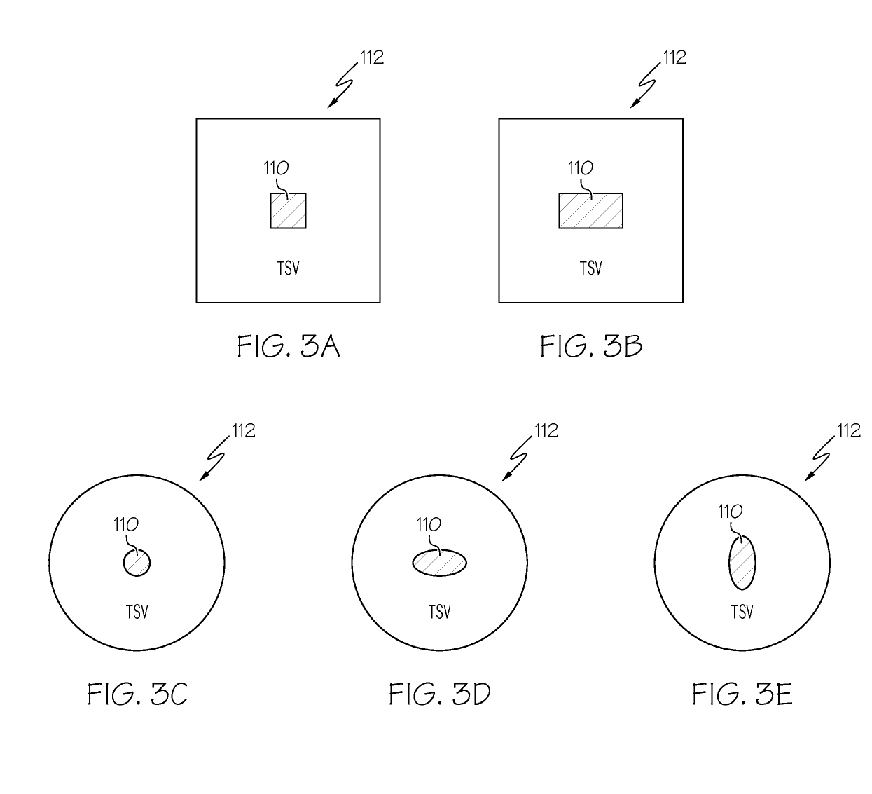

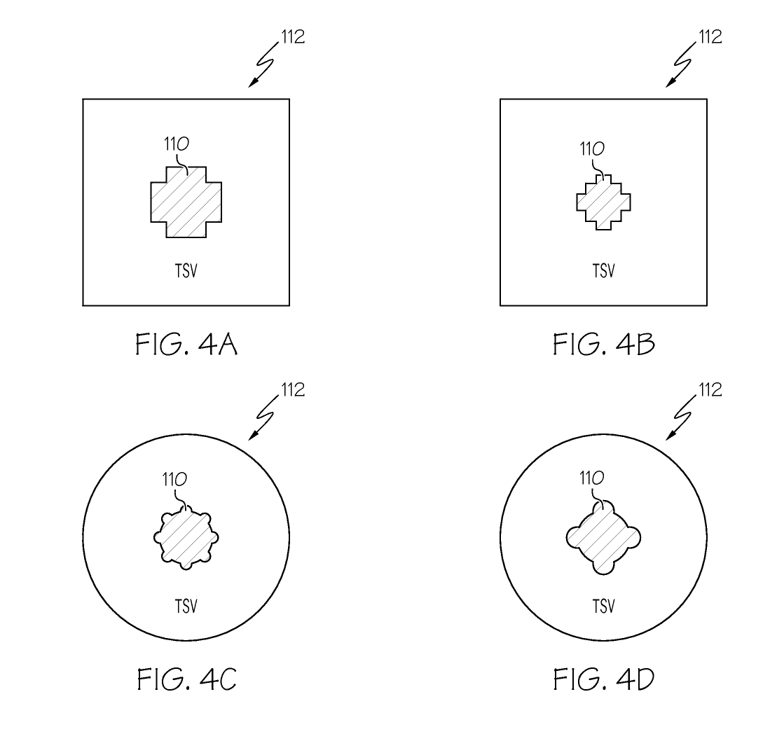

Element 110 may take on a variety of different shapes and forms, as depicted in FIGS. 3(a)-3(e). Here it is demonstrated that TSV 112 and element 110 may each comprise at least one of the following: a substantially circular shape (e.g., FIG. 3(c)), a substantially oval shape (e.g., FIGS. 3(d) and 3(e)), and a substantially rectangular shape (e.g., FIGS. 3(a) and 3(b)). FIGS. 4(a)-4(d) demonstrate that element 110 may be even more varied, the configuration selected (e.g., by a designer) for maximum effectiveness.

In one embodiment, the layout (i.e., a representation of an IC structure, or portion thereof, in terms of planar geometric shapes, which correspond to the design masks that pattern the metal layers, the oxide regions, the diffusion areas, or other layers) of element 110 is selected to optimize the performance of IC device 100 by reducing the stress to TSV 112. The stress field induced by TSV 112 can be determined using any of a variety of different techniques. In one embodiment, a global analysis of forces and resulting stresses can be performed for a given IC package. Forces can be estimated or measured with the resulting stress fields being developed mathematically. Stress fields can be mathematically modeled, for example, within a single die of the IC package. The macro-model developed for the IC package can be applied and subdivided to provide a micro-model that is applicable at the individual active circuit element level across a die. The local effects of the stresses across the entire interposer, for example, can be evaluated to estimate the stress field from TSV 112 as applied to one or more different active circuit elements. In one aspect, distance between each active circuit element and TSV 112 can be used to evaluate or determine the stress field to which that active circuit element is subjected as induced by TSV 112.

In another embodiment, empirical data can be determined for active circuit elements as measured from test structures constructed with various configurations of TSV 112 and/or active circuit elements. Various operational characteristics of the active circuit element can be measured such as the saturation current of the active circuit element and the like. Measured operational characteristics can be correlated with physical properties of the active circuit element, for example, orientation of the active circuit element compared with TSV location, width of the active circuit element, length of the active circuit element, whether the active circuit element is an N-type of device or a P-type of device, etc. The data measured from actual silicon prototype structures can be used to generate a model for designing an optimized layout design/shape for element 110 and TSV 112.

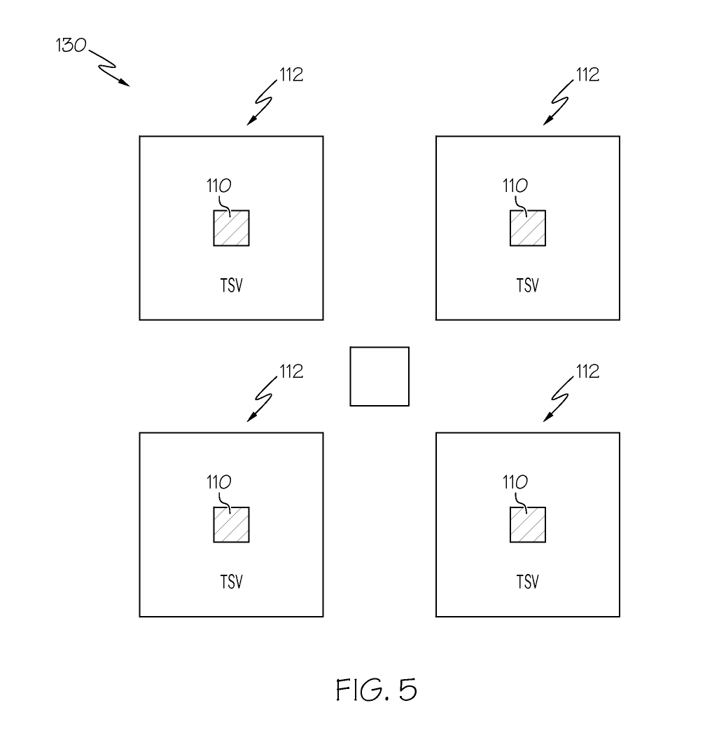

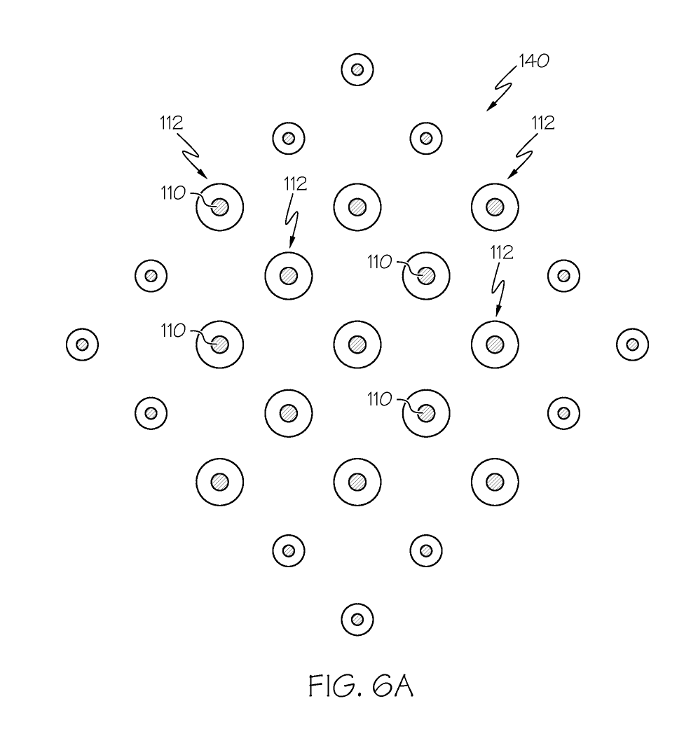

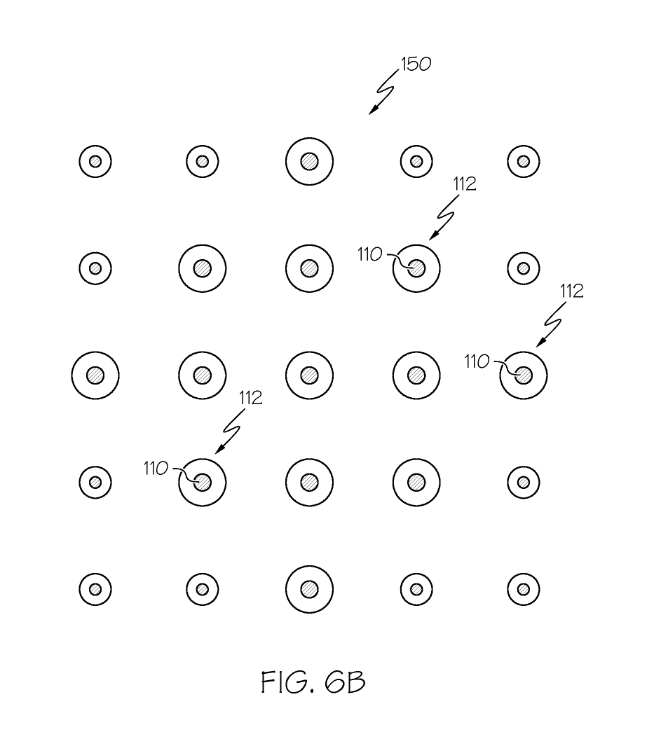

Approaches provided herein also apply to a plurality of TSVs 112, e.g., arranged as shown in FIG. 5. Here, each TSV 112 and element 110 is substantially rectangular shaped, and arranged as a 2×2 matrix 130. This approach may be expanded to larger matrices, as demonstrated in FIGS. 6(a)-6(b). In this embodiment, layout optimization for each array TSV 140 and 150, respectively, includes edge TSVs that are slightly smaller. Those TSVs positioned closer to the center of each TSV array 140 and 150 are sized the same to keep the coverage area to connecting vias (not shown).

In various embodiments, design tools can be provided and configured to create the datasets used to pattern the semiconductor layers as described herein. For example data sets can be created to generate photomasks used during lithography operations to pattern the layers for structures as described herein. Such design tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance on which software runs or in which hardware is implemented. As used herein, a module might be implemented utilizing any form of hardware, software, or a combination thereof. For example, one or more processors, controllers, ASICs, PLAs, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations. Even though various features or elements of functionality may be individually described or claimed as separate modules, one of ordinary skill in the art will understand that these features and functionality can be shared among one or more common software and hardware elements, and such description shall not require or imply that separate hardware or software components are used to implement such features or functionality.

It is apparent that there has been provided approaches for reducing stress in a TSV using a patterned column. While the invention has been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Therefore, it is to be understood that the appended claims are intended to cover all such modifications and changes that fall within the true spirit of the invention.

1. A device comprising:
a substrate; and
a plurality of through-silicon-vias (TSVs) formed in the substrate, the plurality of TSVs each having a substantially vertical element patterned therein, wherein the plurality of TSVs are arranged in a matrix configuration, and wherein a set of TSVs from the plurality of TSVs positioned closer to a center of the matrix are larger in size than another set of TSVs from the plurality of TSVs positioned further away from the center of the matrix.

2. The device of claim 1, the element comprising silicon.

3. The device of claim 1, the TSV further comprising a set of openings adjacent the element.

4. The device according to claim 3, the device further comprising a TSV fill material formed within each of the set of openings adjacent the element.

5. The device of claim 4, the TSV fill material comprising copper.

6. The device according to claim 1, the element comprising at least one of the following: a substantially circular element, a substantially oval-shaped element, and a substantially rectangular shaped element.

7. (canceled)

8. An integrated circuit (IC) device for reducing through-silicon-via (TSV) stress, the IC device comprising:
a substrate; and
a plurality of through-silicon-vias (TSVs) formed in the substrate, the plurality of TSVs each having a substantially vertical element patterned therein, wherein the plurality of TSVs are arranged in a matrix configuration, and wherein a set of TSVs from the plurality of TSVs positioned closer to a center of the matrix are larger in size than another set of TSVs from the plurality of TSVs positioned further away from the center of the matrix.

9. The IC device of claim 8, the element comprising silicon.

10. The IC device of claim 8, the TSV further comprising a set of openings adjacent the element.

11. The IC device according to claim 10, the device further comprising a TSV fill material formed within each of the set of openings adjacent the element.

12. The IC device of claim 11, the TSV fill material comprising copper.

13. The IC device according to claim 8, the element comprising at least one of the following: a substantially circular element, a substantially oval-shaped element, and a substantially rectangular shaped element.

14. (canceled)

15. A method for reducing through-silicon-via (TSV) stress in an integrated circuit (IC) device, the method comprising:
forming plurality of through-silicon-vias (TSVs) formed in the substrate, the plurality of TSVs each having a substantially vertical element patterned therein, wherein the plurality of TSVs are arranged in a matrix configuration, and wherein a set of TSVs from the plurality of TSVs positioned closer to a center of the matrix are larger in size than another set of TSVs from the plurality of TSVs positioned further away from the center of the matrix.

16. The method of claim 15, the element comprising silicon.

17. The method of claim 15, the forming the TSV further comprising patterning a set of openings in the substrate to form the element.

18. The method according to claim 17, further comprising depositing a TSV fill material within each of the set of openings.

19. The method according to claim 15, the element comprising at least one of the following: a substantially circular element, a substantially oval-shaped element, and a substantially rectangular shaped element.

20. (canceled)
